(19) United States
(12) Patent Application Publication
(10) Pub. No.: US 2003/0095381 A1
(43) Pub. Date: May 22, 2003

(54) Electronic card cooling

(76) Inventors: Mario J. Lee, Santa Clara, CA (US); Anthony N. Eberhardt, Los Gatos, CA (US)

Correspondence Address: B. NOEL KIVLIN, Conley, Rose, & Tayon, P.C., P.O. Box 398, Austin, TX, 78767, US

(21) Appl. No.: 10/015,215

(22) Filed: Nov. 19, 2001

(51) Int. Cl. H05K 5/00

(52) U.S. Cl. 361/687; 361/690

(57) ABSTRACT

A computer system including a chassis, which directs cooling airflow to effectively cool electronic cards, such as PCI cards, positioned with a longitudinal axis perpendicular to the airflow, is disclosed. The chassis may include panels that substantially enclose the electronic cards therein. An opening positioned above the cards allows cooling air to flow into the chassis perpendicular to the longitudinal axis of the cards. Another opening allows cooling air to flow out of the chassis parallel to the orientation of the cards and into the existing cooling airflow of the system. The chassis module may be constructed in a computer system to allow increased flexibility of computer system configurations in which multiple cards, boards, or electronic components may need to be positioned perpendicularly to the existing cooling air flow in the system. The module may be implemented in large server systems as well as desktop personal computers without the need of additional cooling fans or vents.

### BACKGROUND OF THE INVENTION

1. Field of the Invention

This invention generally relates to computer systems, and particularly to an apparatus configured to cool electronic cards within a computer system housing.

2. Description of Related Art

Computer systems may include many electronic components or hardware circuit elements such as semiconductor electronic devices in a common housing. During operation, such electronic components may dissipate electrical power (e.g., transform electrical energy into heat energy). At the same time, several key operating parameters of semiconductor electronic devices typically vary with temperature. Reliable device operation may occur only within a defined operating temperature range. It has been established that the reliability of semiconductor electronic devices may decrease with increasing operating temperature. The heat energy produced by electronic components during operation should therefore be removed from the devices at a rate which ensures that operational and reliability requirements of the devices are met. As electronic component speeds, capabilities, and density increase, so does the amount of electrical power dissipated by the electronic components during operation. Current cooling mechanisms employed by computer systems allow for airflow into the computer system housing. The flow of air through the computer system housing allows the transfer of heat from the electronic components within the computer system housing to the surrounding ambient air. Various openings or vents, in conjunction with one or more fans, may allow ambient air to flow through a computer system housing. Ambient air may be drawn into the computer system housing by fans. The ambient air flows over the electronic components within the computer system housing. The ambient air absorbs heat energy from the electronic components before being expelled through the openings or vents in the computer system housing.

Heat sensitive electronic components may include system boards, power supply units, CPU modules, graphics cards, disk drives, PCI cards, and other I/O components. Most computer systems may not allow all of the components to be oriented within the system such that all of the electronic components receive the most effective cooling. Cooling effectiveness may depend on the number, location, and orientation of electronic components, and/or the number and location of cooling fans, vents or openings in the computer system housing.

A computer system housing has a volume limited by the sides of the computer system housing. Further, a larger number of electronic components that are housed within the computer system housing may necessitate proportionate availability of adequate cooling means for reliable operation of the computer system. Therefore, the electronic component packing density within the computer system housing may determine the airflow through the computer system electronic components.

Traditionally, electronic cards (e.g., video cards, audio cards, control cards, modem cards, IDE cards, AGP cards, and PCI-type cards) have been arranged vertically in sockets on a motherboard. Cooling of the electronic components on the electronic cards may be less than optimal due to this vertical arrangement. A low profile extender configuration may be used in which the motherboard includes a connector for a riser card. In this configuration, electronic cards arranged in the connectors of the riser card may lie parallel to the plane of the motherboard. Cooling of the electronic components may be improved with the electronic cards in a horizontal arrangement.

In some cases, the longitudinal axis of electronic cards may be oriented at a right angle to the airflow direction. This arrangement may create a cooling problem in that adjacent electronic cards downstream from an electronic card proximate the incoming air stream will be “shadowed” from the cooling air. The electronic card proximate the incoming air stream, may block the air from reaching any adjacent electronic card downstream.

### SUMMARY OF THE INVENTION

A computer system includes a chassis in which various electronic components may be mounted and housed. The computer system may include a cooling system to draw air (e.g., ambient air) into the chassis, and draw air out of the chassis to the surroundings. Electronic cards may be coupled to a main system I/O board of the computer system (e.g., a motherboard). Electronic cards include, but are not limited to, video cards, audio cards, control cards, modem cards, IDE cards, AGP cards, and PCI cards.

In an embodiment, multiple electronic cards may be positioned such that a longitudinal axis of each of the electronic cards is perpendicular to a cooling airflow stream in the chassis. Multiple panels may form a module into which the electronic cards may be located. A cooling airflow stream may enter the module through an opening above the row of electronic cards. The module may direct the cooling airflow stream parallel to a longitudinal axis of the electronic cards and along at least one face of each electronic card. The cooling airflow is drawn out of the module through another opening and joins an airflow stream through the rest of the chassis.

### BRIEF DESCRIPTION OF THE DRAWINGS

Further advantages of the disclosed device and method will become apparent to those skilled in the art with the benefit of the following detailed description of the embodiments and upon reference to the accompanying drawings in which:

FIG. 1 depicts a side view layout of a computer system cabinet for housing electronic assemblies;

FIG. 2 depicts a front view layout of another embodiment of a computer system cabinet for housing electronic assemblies;

FIG. 3 depicts a perspective view of an electronic card assembly;

FIG. 4 depicts a perspective view of an embodiment of a module enclosing a plurality of electronic cards;

FIG. 5 depicts a front perspective view of an embodiment of a chassis module enclosing a plurality of electronic cards;

FIG. 6 depicts a rear perspective view of the embodiment of the chassis module of FIG. 5; and

FIG. 7 depicts a side perspective view of the embodiment of FIG. 5 partially installed in a portion of a computer system cabinet.

While the invention is susceptible to various modifications and alternative forms, specific embodiments thereof are shown by way of example in the drawings and will herein be described in detail. The drawings may not be to scale. It should be understood, however, that the drawings and detailed description thereto are not intended to limit the invention to the particular form disclosed, but on the contrary, the intention is to cover all modifications, equivalents and alternatives falling within the spirit and scope of the present invention as defined by the appended claims.

### DETAILED DESCRIPTION OF EMBODIMENTS OF THE INVENTION

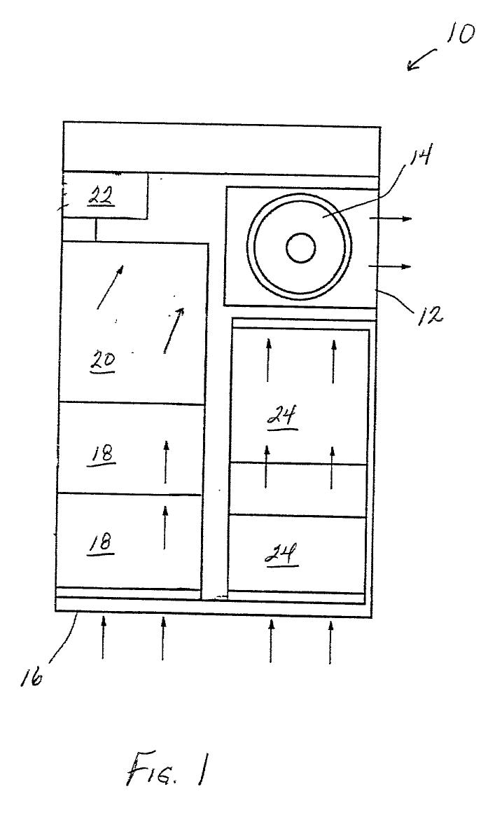

Referring to the figures, FIG. 1 represents an embodiment of an industry standard rack mount computer system cabinet or server 10. Alternatively, the computer system may be arranged in a horizontal direction, as in a desktop personal computer. The computer system includes a cooling system 12 which may include at least one air control device 14, such as a fan or blower, proximate the upper portion of the cabinet, and openings or vents (not shown) proximate a lower portion 16 of the cabinet. The computer system may include several modules of various electronic components 18. All of the electronic components may generate heat and require cooling during use. For example, in FIG. 1, the computer system may include electronic components such as a processor, memory modules, and/or high power devices. The computer system may also include a power module 20, and a series of storage drives 22, such as floppy disc, CD ROM, DVD and/or tape drives. Electronic cards may be located in areas 24.

Air may be drawn from the computer surroundings through the lower portion 16 of the cabinet. The air may serially cool the electronic assemblies and components 18, electronic cards 24, power module 20, and storage drives 22 as it is pulled through the cabinet with the fan 14. The main airflow path through the computer may be as indicated by the arrows in FIG. 1.

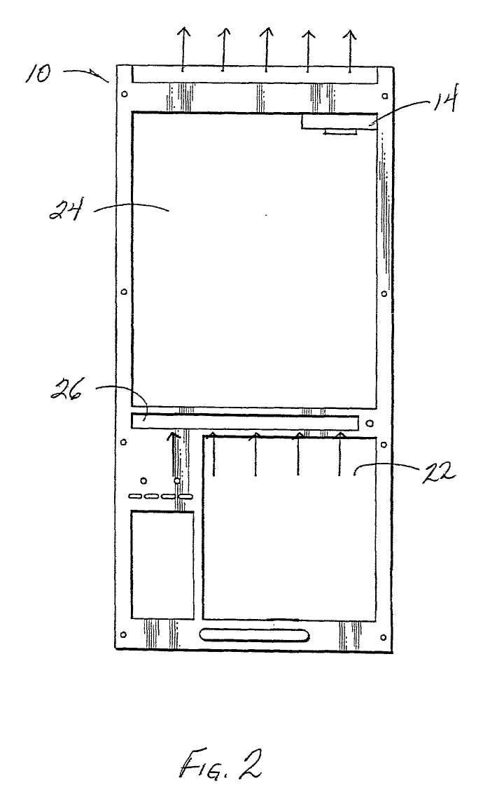

Another embodiment of a computer system is depicted in FIG. 2. In FIG. 2, storage drives 22 may be proximate a lower end of the computer, and one or more electronic cards 24 may be located proximate an upper end of the computer. Vents may be arranged at a location 26 below the electronic cards 24 to draw air into the system. An exhaust fan 14 may be located above the electronic cards 24 to exhaust air out proximate an upper portion of the system.

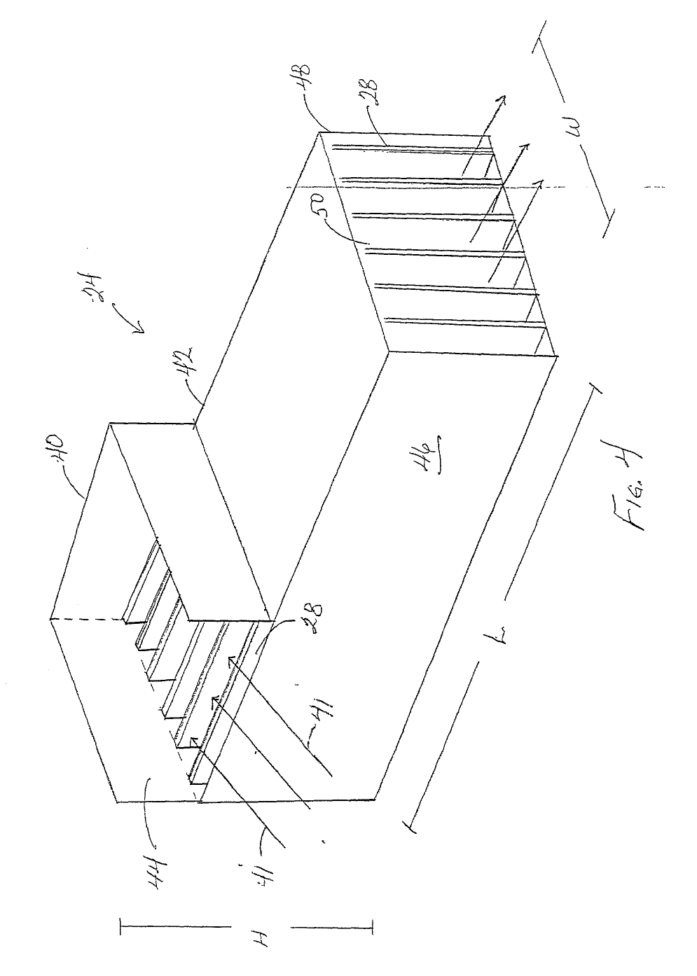

Typically, a main system board, or motherboard, is located vertically within the cabinet so as not to block the main airflow path through the cabinet. A longitudinal axis of electronic cards connected to the motherboard may be oriented such that the face of a card is perpendicular to the main airflow path through the computer (refer to FIG. 4). The electronic card facing the incoming airflow may block cooling air from reaching other electronic cards nearby.

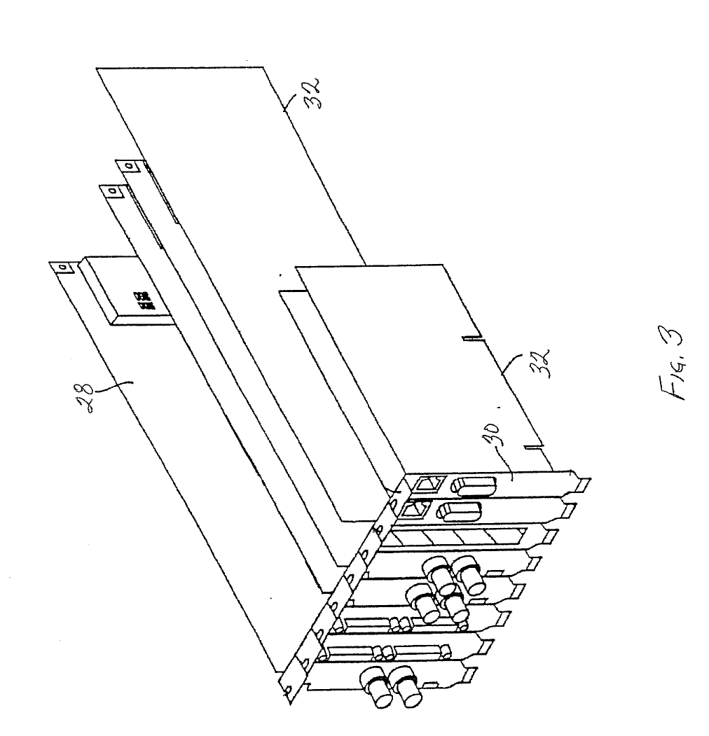

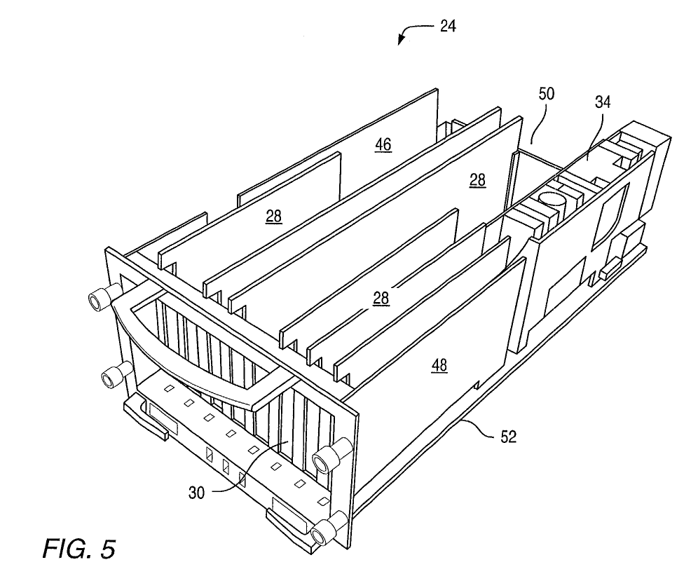

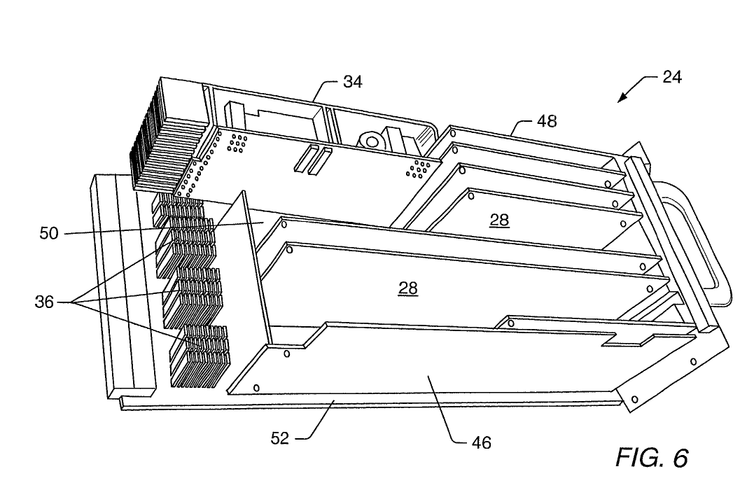

An embodiment of an electronic card assembly is depicted in FIG. 3. In FIG. 3, electronic cards (e.g., PCI cards) 28 are oriented parallel to one another. Each electronic card includes a mounting bracket 30 attached to an end of the electronic card. Mounting brackets 30 may be secured to the chassis or housing of the computer system by means well known in the art, such as with screws. External connections may be made through the mounting brackets 30 to each of the electronic cards. Bottom edge 32 of each of the electronic cards may be affixed to the motherboard through normal means such as through an edge connector. Blanks or filler cards may occupy empty slots, in the absence of a functional electronic card. Various other components may also be included with the electronic card assembly, such as a voltage regulator 34 and heatsinks 36, as shown in FIGS. 5 and 6.

FIG. 4 shows an embodiment of a module 24 enclosing a series of electronic cards 28. Module 24 may include a flange 40 proximate the front of the module. Flange 40 extends above an upper edge of electronic cards 28. Flange 40 also extends above body 42 of module 24. Flange 40 may define an opening 44, which is positionable in the direction of an incoming cooling airflow path depicted as arrows 41, when the module is mounted in a computer system. A top portion of flange 40 (not shown) may be formed by an inner surface of a sidewall of a computer housing or cabinet 10. Alternatively, a top portion of flange 40 may be formed as an integral part of module 24.

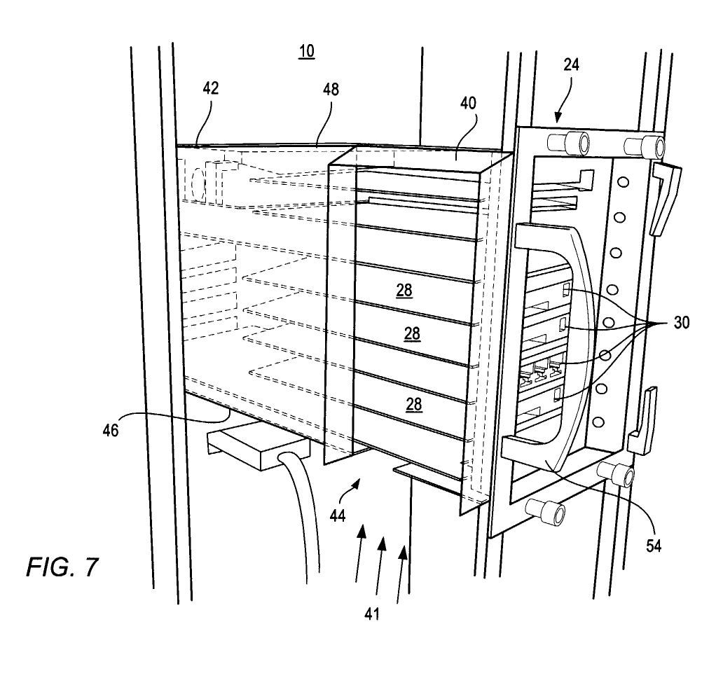

Flange 40 may be coupled to body 42 of module 24, or may be attached to an inner wall of a computer system chassis. Body 42 may include first panel 46 and second panel 48 located on either side of the series of electronic cards 28. First panel 46 and second panel 48 may form a second opening 50 through which the air flows out of module 24. Panels 46 and 48 may be part of the chassis of the computer system. Alternatively, panels 46 and 48 may be affixed to a portion of the chassis or a portion of a main system board. The module may be made of sheet metal or other appropriate material. A length L of first and second panels 46 and 48, respectively, may be longer than a length of the longest electronic card 28 in module 24. Similarly, a height H of the module may be greater than a height of electronic cards 28, and less than a width of a rack into which module 24 will be located in the system (see FIG. 7). Width W of body 42 of module 24 may be determined by the number of electronic cards 28 in the assembly or a height of the rack into which module 24 will be located in the system (see FIG. 7).

Opening 44 extends above a top edge of electronic cards 28 in module 24. Opening 44 may be sized depending on the amount of cooling air needed for module 24. As such, cooling air flowing perpendicular to a longitudinal axis of the electronic cards is directed through opening 44 of flange 40 above the electronic cards. The walls of flange 40 redirect the incoming airflow down through electronic cards 28, parallel to the longitudinal axis and along the face of each of the electronic cards. The air exits the electronic card assembly through second opening 50 where it joins a main airflow path of the system. The exiting air may cross over heatsinks 36 proximate second opening 50 as it joins the main airflow stream (see FIG. 6).

FIGS. 5 and 6 show an embodiment of a portion of a module 24 formed by portions of a chassis of a computer system. As depicted in the embodiment of FIG. 5, a portion of the module 24 includes panels 46 and 48. A portion of the module 24 also includes a portion of the chassis to which mounting brackets 30 of electronic cards 28 may be fastened. A main system board 52 may form the bottom of the body 42. Other components may also be included on the main system board 52, such as a voltage regulator 34 and heatsinks 36 (see FIG. 6).

A cooling air stream flowing perpendicularly to a longitudinal axis of the electronic cards 28 enters into the module 24 above the electronic cards. The cooling air stream is redirected to flow parallel to the longitudinal axis and through the assembly of the electronic cards 28, and exits the module 24 through second opening 50 where it joins the main airflow path of the system. The exiting air may cross over heatsinks 36 proximate second opening 50 as it joins the main airflow stream (see FIG. 6).

FIG. 7 shows an embodiment of module 24 described herein in an exemplary installation position in a computer system cabinet 10, such as a server system. Handle 54 may be used for inserting module 24 in and removing the module from the cabinet. A top portion of flange 40 of module 24 is formed by an inner wall of the chassis (not shown). Alternatively, the top portion of flange 40 may be formed as an integral part of module 24. As shown in FIG. 7, opening 44 of flange 40 is positioned in the direction of incoming airflow path 41 toward the front of the computer system cabinet 10. When module 24 is fully inserted into the rack, flange 40 is adjacent to the inner wall of the chassis to form and enclose the top portion of the flange.

In an alternate embodiment, flange 40 of module 24 may be attached to an inner wall of the chassis toward the front of the computer system cabinet 10. When module 24 is fully inserted into the rack, flange 40 is adjacent to panels 46 and 48 of the body 42 of the module.

A portion of the module 24 is formed by a portion of the chassis to which the mounting brackets 30 of electronic cards 28 faces toward the front of the computer system cabinet 10. The cooling air stream 41 enters module 24 from below the electronic cards 28, is directed over and through the cards, and exits second opening 50 (not shown) toward the back of the module and computer system cabinet 10.

Module 24, or a portion of the module, such as flange 40 or body 42, may be removably or fixedly attached to the chassis of the system and/or to main system board 52. Alternatively, module 24 may be part of the chassis or may be implemented as a separate module or separate panels that attach onto the chassis or main system board 52 of the computer system. The separate module or panels may be affixed to the computer system with fasteners, such as adhesive tapes, rivets, screws, nuts and bolts, brackets, etc., to securely mount the module and/or panels on appropriate surfaces. As such, module 24 may be implemented in substantially smaller and larger computer systems, including desktop personal computers. An embodiment of the module or multiple modules 24 may be used to provide cooling to other electronic components which may require cooling and are oriented with a longitudinal axis perpendicular to the main cooling airflow of the computer system. The module may be constructed and formed of any appropriate material, such as sheet metal, stainless steel, a polycarbonate or acrylic, or a combination thereof.

Further modifications and alternative embodiments of various aspects of the invention will be apparent to those skilled in the art in view of this description. Accordingly, this description is to be construed as illustrative only and is for the purpose of teaching those skilled in the art the general manner of carrying out the invention. It is to be understood that the forms of the invention shown and described herein are to be taken as examples of embodiments. Elements and materials may be substituted for those illustrated and described herein, parts and processes may be reversed, and certain features of the invention may be utilized independently, all as would be apparent to one skilled in the art after having the benefit of this description of the invention. Changes may be made in the elements described herein without departing from the spirit and scope of the invention as described in the following claims.

What is claimed is:

1. A computer system, comprising:
a chassis;
a main system board disposed within the chassis;
a plurality of electronic cards mounted to the main system board; and
a module at least partially surrounding the plurality of electronic cards;
wherein the module is configured to redirect an air stream moving through the chassis in a substantially perpendicular direction to a longitudinal axis of the plurality of electronic cards to a direction substantially parallel to the longitudinal axis of the cards such that the air stream passes over the plurality of electronic cards.

2. The system of claim 1, wherein the module is coupled to a portion of the chassis.

3. The system of claim 1, wherein the module is removably coupled to a portion of the chassis.

4. The system of claim 1, wherein the module is removably coupled to the main system board.

5. The system of claim 1, wherein the module is coupled to the main system board.

6. The system of claim 1, wherein the module comprises a flange, the flange defining an opening configured to allow the air stream to enter the module.

7. The system of claim 1, wherein the module comprises a flange, the flange defining an opening configured to allow the air stream to enter the module above the plurality of electronic cards.

8. The system of claim 6, wherein the flange is coupled to a portion of the chassis.

9. The system of claim 6, wherein the flange is removably coupled to a portion of the chassis.

10. The system of claim 1, wherein the plurality of electronic cards are PCI cards.

11. The system of claim 1, wherein the computer system is a server.

12. The system of claim 1, wherein the computer system is a desktop personal computer.

13. A module for a computer system, comprising:
a main system board disposed within the module;
a plurality of electronic cards mounted to the main system board; and
wherein the module is configured to redirect an air stream through the computer system from a substantially perpendicular direction to a longitudinal axis of the electronic cards to a direction substantially parallel to the longitudinal axis of the cards such that the air stream passes over the plurality of electronic cards, and wherein the module is removable coupled to the computer system.

14. The system of claim 13, wherein the module at least partially surrounds the plurality of electronic cards.

15. The system of claim 13, wherein at least a portion of the module comprises a portion of a chassis of the computer system.

16. The system of claim 13, wherein the module comprises a flange, the flange defining an opening configured to allow the air stream to enter the module.

17. The system of claim 13, wherein the plurality of electronic cards are PCI cards.

18. A method of cooling electronic cards in a computer system, comprising:
providing a module at least partially surrounding a plurality of electronic cards disposed in a chassis of the computer system;
directing an air stream moving in a substantially perpendicular direction to a longitudinal axis of the plurality of electronic cards into the module, wherein the module redirects the air stream to a direction substantially parallel to the longitudinal axis of the plurality of electronic cards; and
passing the cooling air stream over the electronic cards and out of the module.

19. The method of claim 18, wherein the module is coupled to a portion of the chassis.

20. The method of claim 18, wherein the module is removably coupled to a portion of a chassis.

21. The method of claim 18, wherein the module is coupled to a main system board of the computer system.

22. The method of claim 18, wherein the module is removably coupled to a main system board of the computer system.

23. The method of claim 18, wherein the computer system comprises a server.

24. The method of claim 18, wherein the computer system comprises a desktop personal computer.

25. The method of claim 18, wherein directing the air stream into the module comprises directing the air stream through an opening in a flange of the module.

26. The method of claim 18, wherein directing the air stream into the module comprises directing the air stream above the plurality of electronic cards through an opening in a flange of the module.

27. The method of claim 18, wherein the plurality of electronic cards are PCI cards.
